(19) United States
(12) Patent Application Publication
(10) Pub. No.: US 2019/0081183 A1
(43) Pub. Date: Mar. 14, 2019

(54) OXIDE SEMICONDUCTOR DEVICE AND MANUFACTURING METHOD THEREOF

(71) Applicant: UNITED MICROELECTRONICS CORP., Hsin-Chu City (TW)

(72) Inventors: Xiang Li, Singapore (SG); Shao-Hui Wu, Singapore (SG); HSIAO YU CHIA, Singapore (SG); Yu-Cheng Tung, Kaohsiung City (TW)

(21) Appl. No.: 15/784,176

(22) Filed: Oct. 15, 2017

(30) Foreign Application Priority Data
Sep. 12, 2017 (TW) 106131227

(51) Int. Cl. H01L 29/786; H01L 29/66; H01L 29/40; H01L 29/10; H01L 29/423

(52) U.S. Cl. CPC H01L 29/78696; H01L 29/7869; H01L 29/42376; H01L 29/401; H01L 29/1037; H01L 29/66969

(57) ABSTRACT

An oxide semiconductor device includes a substrate, a first patterned oxide semiconductor channel layer, a second oxide semiconductor channel layer, a gate dielectric layer, and a gate electrode. The first patterned oxide semiconductor channel layer is disposed on the substrate. The second patterned oxide semiconductor channel layer is disposed on the first patterned oxide semiconductor channel layer and covers a side edge of the first patterned oxide semiconductor channel layer. The gate dielectric layer is disposed on the second patterned oxide semiconductor channel layer. A top surface of the second patterned oxide semiconductor channel layer is fully covered by the gate dielectric layer. The gate electrode is disposed on the gate dielectric layer. A projection area of the gate electrode in a thickness direction of the substrate is smaller than a projection area of the second patterned oxide semiconductor channel layer in the thickness direction.

### BACKGROUND OF THE INVENTION

### 1. Field of the Invention

The present invention relates to an oxide semiconductor device and a manufacturing method thereof, and more particularly, to an oxide semiconductor device including oxide semiconductor channel layers and a manufacturing method thereof.

### 2. Description of the Prior Art

Oxide semiconductor materials, such as indium gallium zinc oxide (IGZO), have been applied in thin film transistors (TFTs) of display devices and field effect transistors (FETs) used in integrated circuits because of properties such as high mobility and low leakage current. However, the semiconductor characteristics of the oxide semiconductor materials are directly dominated by the condition of oxygen vacancies in the oxide semiconductor materials, and the condition of oxygen vacancies in the oxide semiconductor layer tends to be influenced easily by other processes and/or environment substances, such as moisture, oxygen, and hydrogen, and the stability and reliability of the oxide semiconductor device will be affected. Accordingly, for the related industries, it is important to improve the electrical stability and the product reliability of the oxide semiconductor device.

### SUMMARY OF THE INVENTION

An oxide semiconductor device and a manufacturing method thereof are provided in the present invention. A top surface of a patterned oxide semiconductor channel layer is completely covered by a gate dielectric layer for controlling a size of the patterned oxide semiconductor channel layer. The stability and uniformity of electrical performance of the oxide semiconductor device may be improved accordingly.

According to an embodiment of the present invention, an oxide semiconductor device is provided. The oxide semiconductor device includes a substrate, a first patterned oxide semiconductor channel layer, a second patterned oxide semiconductor channel layer, a gate dielectric layer, and a gate electrode. The first patterned oxide semiconductor channel layer is disposed on the substrate. The second patterned oxide semiconductor channel layer is disposed on the first patterned semiconductor channel layer. A side edge of the first patterned oxide semiconductor channel layer is covered by the second patterned oxide semiconductor channel layer. The gate dielectric layer is disposed on the second patterned oxide semiconductor channel layer. A top surface of the second pattern oxide semiconductor channel layer is fully covered by the gate dielectric layer. The gate electrode is disposed on the gate dielectric layer. A projection area of the gate electrode in a thickness direction of the substrate is smaller than a projection area of the second patterned oxide semiconductor channel layer in the thickness direction.

According to an embodiment of the present invention, a manufacturing method of an oxide semiconductor device is provided. The manufacturing method includes the following steps. Firstly, a substrate is provided. A first patterned oxide semiconductor channel layer is formed on the substrate. A second patterned oxide semiconductor channel layer is formed on the first patterned oxide semiconductor channel layer. A side edge of the first patterned oxide semiconductor channel layer is covered by the second patterned oxide semiconductor channel layer. A gate dielectric layer is formed on the second patterned oxide semiconductor channel layer. A top surface of the second pattern oxide semiconductor channel layer is fully covered by the gate dielectric layer. A gate electrode is formed on the gate dielectric layer. A projection area of the gate electrode in a thickness direction of the substrate is smaller than a projection area of the second patterned oxide semiconductor channel layer in the thickness direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view schematic drawing illustrating an oxide semiconductor device according to a first embodiment of the present invention.

FIG. 2 is a cross-sectional diagram taken along a line A-A′ in FIG. 1.

FIG. 3 is a cross-sectional diagram taken along a line B-B′ in FIG. 1.

FIGS. 4-6 are schematic drawings illustrating a manufacturing method of the oxide semiconductor device according to the first embodiment of the present invention, wherein

FIG. 5 is a schematic drawing in a step subsequent to FIG. 4, and

FIG. 6 is a schematic drawing in a step subsequent to FIG. 5.

FIG. 7 is a top view schematic drawing illustrating an oxide semiconductor device according to a second embodiment of the present invention.

FIG. 8 is a cross-sectional diagram taken along a line C-C′ in FIG. 7.

FIG. 9 is a cross-sectional diagram taken along a line D-D′ in FIG. 7.

FIG. 10 is a top view schematic drawing illustrating an oxide semiconductor device according to a third embodiment of the present invention.

FIG. 11 is a cross-sectional diagram taken along a line E-E′ in FIG. 10.

### DETAILED DESCRIPTION

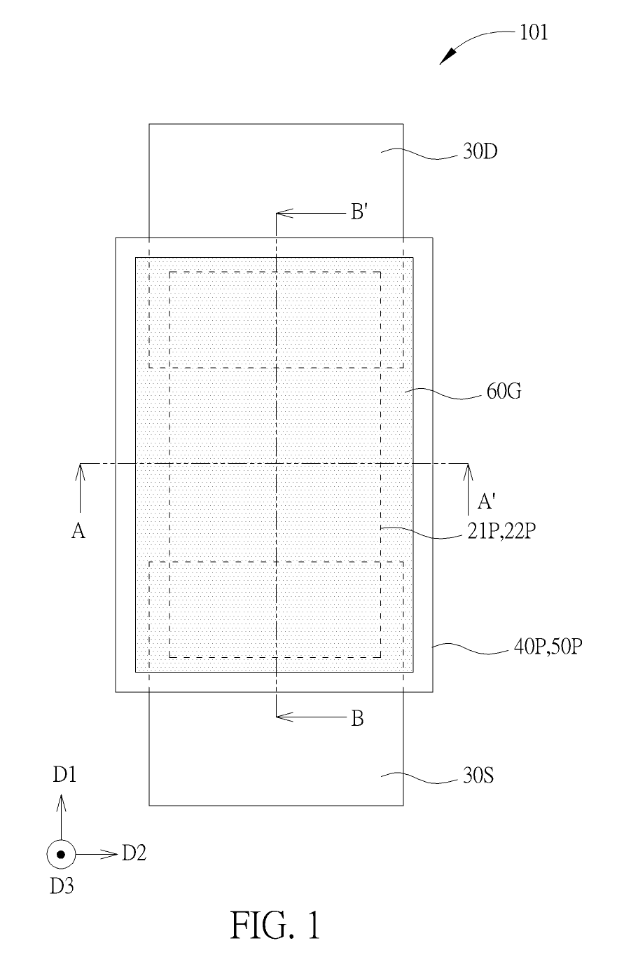

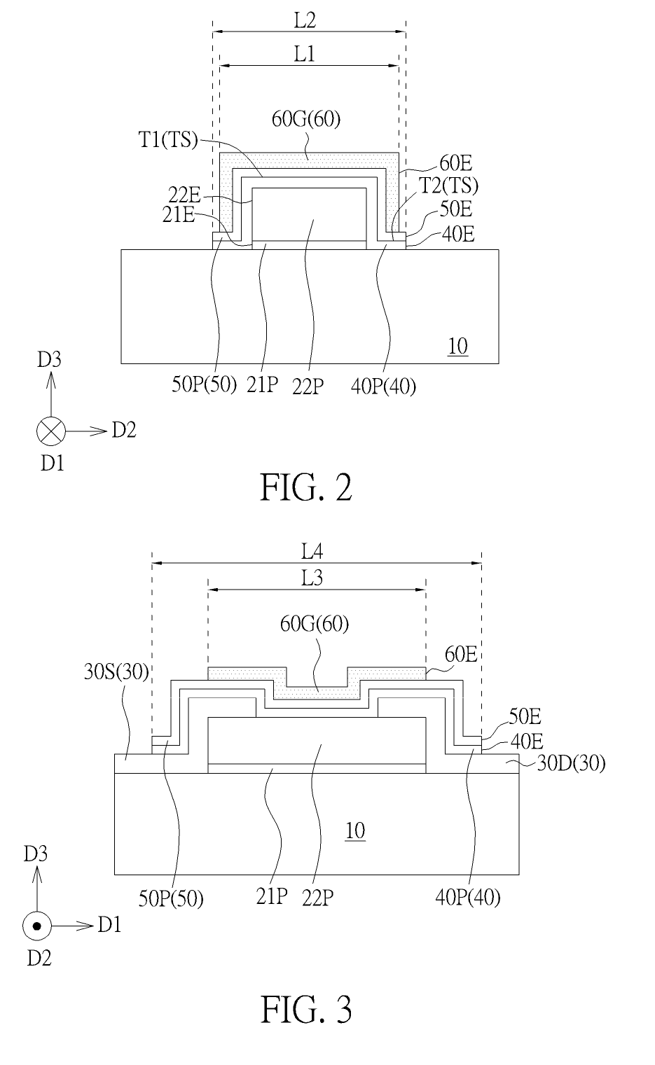

Please refer to FIGS. 1-3. FIG. 1 is a top view schematic drawing illustrating an oxide semiconductor device according to a first embodiment of the present invention, FIG. 2 is a cross-sectional diagram taken along a line A-A′ in FIG. 1, and FIG. 3 is a cross-sectional diagram taken along a line B-B′ in FIG. 1. As shown in FIGS. 1-3, an oxide semiconductor device 101 is provided in this embodiment. The oxide semiconductor device 101 includes a substrate 10, a first patterned oxide semiconductor channel layer 22P, a second patterned oxide semiconductor channel layer 40P, a gate dielectric layer 50P, and a gate electrode 60G. The first patterned oxide semiconductor channel layer 22P is disposed on the substrate 10. The substrate 10 may include a non-semiconductor substrate or an insulation layer formed on a semiconductor substrate. The non-semiconductor substrate mentioned above may include a glass substrate, a plastic substrate, or a ceramic substrate, and the semiconductor substrate mentioned above may include silicon substrate, silicon germanium substrate, or silicon-on-insulator (SOI) substrate, but not limited thereto. The second patterned oxide semiconductor channel layer 40P is disposed on the first patterned semiconductor channel layer 22P, and a side edge (such as a second side edge 22E shown in FIG. 2) of the first patterned oxide semiconductor channel layer 22P is covered by the second patterned oxide semiconductor channel layer 40P. The gate dielectric layer 50P is disposed on the second patterned oxide semiconductor channel layer 40P, and a top surface TS of the second pattern oxide semiconductor channel layer 40P is fully covered by the gate dielectric layer 50P. The gate electrode 60G is disposed on the gate dielectric layer 50P. A projection area of the gate electrode 60G in a thickness direction D3 of the substrate 10 (such as an area marked with 60G in FIG. 1) is smaller than a projection area of the second patterned oxide semiconductor channel layer 40P in the thickness direction D3 (such as an area marked with 40P in FIG. 1). In some embodiments, the oxide semiconductor device 101 may be regarded as an oxide semiconductor field effect transistor (FET), the first patterned oxide semiconductor channel layer 22P may be regarded as an island shaped channel region in the oxide semiconductor device 101, and the gate dielectric layer 50P and the second patterned oxide semiconductor channel layer 40P may be formed and defined by one identical patterning process for controlling the area of the second patterned oxide semiconductor channel layer 40P. The overlapped area between the second patterned oxide semiconductor channel layer 40P and the gate electrode 60G outside the island shaped channel region may be reduced, and the problem that the effective channel width of the oxide semiconductor device 101 becomes unstable because of the thickness variation of the second patterned oxide semiconductor channel layer 40P may be avoided accordingly. In other words, stability of electrical performance of the oxide semiconductor device 101 and uniformity of electrical performances of oxide semiconductor devices disposed on the same substrate 10 may be improved by controlling the area of the second patterned oxide semiconductor channel layer 40P.

Specifically, in some embodiments, the gate dielectric layer 50P and the second patterned oxide semiconductor channel layer 40P may be defined and formed by the same patterning process, and a side edge (such as a third side edge 40E shown in FIG. 2) of the second patterned oxide semiconductor channel layer 40P may be aligned with a side edge (such as a fourth side edge 50E shown in FIG. 2) of the gate dielectric layer 50P. In some embodiments, the third side edge 40E of the second patterned oxide semiconductor channel layer 40P and the fourth side edge 50E of the gate dielectric layer 50P may be substantially aligned and cut flush with each other in the thickness direction D3 of the substrate 10, but not limited thereto. Additionally, the oxide semiconductor device 101 may further include a source electrode 30S and drain electrode 30D. The source electrode 30S and the drain electrode 30D are disposed at two opposite sides of the first patterned oxide semiconductor channel layer 22P in a first direction D1 respectively. In some embodiments, the source electrode 30S and the drain electrode 30D may be partly disposed on the first patterned oxide semiconductor channel layer 22P and partly disposed on the substrate 10, and a part of the source electrode 30S and a part of the drain electrode 30D may be covered by the second patterned oxide semiconductor channel layer 40P, but not limited thereto. Additionally, in some embodiments, a length (such as a first length L1 shown in FIG. 2) of the gate electrode 60G in a second direction D2 orthogonal to the first direction D1 may be shorter than a length (such as a second length L2 shown in FIG. 2) of the second patterned oxide semiconductor channel layer 40P in the second direction D2, and a length (such as a third length L3 shown in FIG. 3) of the gate electrode 60G in the first direction D1 may be shorter than a length (such as a fourth length L4 shown in FIG. 3) of the second patterned oxide semiconductor channel layer 40P in the first direction D1, but not limited thereto. Additionally, in some embodiments, the oxide semiconductor devise 101 may further include a third patterned oxide semiconductor channel layer 21P disposed between the first patterned oxide semiconductor channel layer 22P and the substrate 10, and a side edge (such as a first side edge 21E shown in FIG. 2) of the third patterned oxide semiconductor channel layer 21P may be covered by the second patterned oxide semiconductor channel layer 40P. In some embodiments, the third patterned oxide semiconductor channel layer 21P and the first patterned oxide semiconductor channel layer 22P may be formed and defined by the same patterning process, and the first side edge 21E of the third patterned oxide semiconductor channel layer 21P may be substantially aligned and cut flush with the second side edge 22E of the first patterned oxide semiconductor channel layer 22P in the thickness direction D3 of the substrate 10, but not limited thereto.

In some embodiments, the source electrode 30S and the drain electrode 30D may be formed by patterning a conductive layer 30, and the gate electrode 60G may be formed by patterning a gate material layer 60. The conductive layer 30 and the gate material layer 60 may respectively include tungsten (W), aluminum (Al), copper (Cu), titanium aluminide (TiAl), titanium (Ti), titanium nitride (TiN), tantalum (Ta), tantalum nitride (TaN), titanium aluminum oxide (TiAlO), or other suitable conductive materials. The gate dielectric layer 50P may include silicon oxide, silicon oxynitride, high dielectric constant (high-k) materials, or other suitable dielectric materials. The high-k materials mentioned above may include hafnium oxide (HfO₂), hafnium silicon oxide (HfSiO₄), hafnium silicon oxynitride (HfSiON), aluminum oxide (Al₂O₃), tantalum oxide (Ta₂O₅), zirconium oxide (ZrO₂), or other appropriate high-k materials. The first patterned oxide semiconductor channel layer 22P, the second patterned oxide semiconductor channel layer 40P, and the third patterned oxide semiconductor channel layer 21P may respectively include II-VI compounds (such as zinc oxide, ZnO), II-VI compounds doped with alkaline-earth metals (such as zinc magnesium oxide, ZnMgO), II-VI compounds doped with IIIA compounds (such as indium gallium zinc oxide, IGZO), II-VI compounds doped with VA compounds (such as stannum stibium oxide, SnSbO₂), II-VI compounds doped with VIA compounds (such as zinc selenium oxide, ZnSeO), II-VI compounds doped with transition metals (such as zinc zirconium oxide, ZnZrO), or other oxide semiconductor materials composed of mixtures of the above-mentioned elements, but not limited thereto. Additionally, the first patterned oxide semiconductor channel layer 22P, the second patterned oxide semiconductor channel layer 40P, and the third patterned oxide semiconductor channel layer 21P may be a single layer or a multiple layer structure formed by the above-mentioned oxide semiconductor materials, and the crystalline conditions of the first patterned oxide semiconductor channel layer 22P, the second patterned oxide semiconductor channel layer 40P, and the third patterned oxide semiconductor channel layer 21P are also not limited. For example, the first patterned oxide semiconductor channel layer 22P, the second patterned oxide semiconductor channel layer 40P, and the third patterned oxide semiconductor channel layer 21P may be amorphous IGZO (a-IGZO), crystal IGZO (c-IGZO), or C-axis aligned crystal IGZO (CAAC-IGZO). Additionally, in some embodiments, the second patterned oxide semiconductor channel layer 40P and the third patterned oxide semiconductor channel layer 21P may be used as barrier layers surrounding the first patterned oxide semiconductor channel layer 22P for keeping unwanted materials, such as silicon, from entering the first patterned oxide semiconductor channel layer 22P and influencing the semiconductor characteristics of the first patterned oxide semiconductor channel layer 22P. An energy level of a bottom of a conduction band of the first patterned oxide semiconductor channel layer 22P may be lower than an energy level of a bottom of a conduction band of the second patterned oxide semiconductor channel layer 40P and an energy level of a bottom of a conduction band of the third patterned oxide semiconductor channel layer 21P preferably, but not limited thereto. Additionally, in some embodiments, an electrical resistivity of the first patterned oxide semiconductor channel layer 22P may be higher than an electrical resistivity of the second patterned oxide semiconductor channel layer 40P and an electrical resistivity of the third patterned oxide semiconductor channel layer 21P, but not limited thereto.

The top surface TS of the second patterned oxide semiconductor channel layer 40P may be completely covered by the gate dielectric layer 50P because the gate dielectric layer 50P and the second patterned oxide semiconductor channel layer 40P may be formed and defined by the same patterning process. For example, the top surface TS of the second patterned oxide semiconductor channel layer 40P may include a first part T1 and a second part T2. The first part T1 may be disposed on an island shaped channel region composed of the first patterned oxide semiconductor channel layer 22P and the third patterned oxide semiconductor channel layer 21P, and the second part T2 may be disposed on the region outside the island shaped channel region mentioned above. The gate dielectric layer 50P may completely cover the first part T1 and the second part T2 of the top surface TS of the second patterned oxide semiconductor channel layer 40P. Additionally, in some embodiments, a projection area of the gate dielectric layer 50P in the thickness direction D3 of the substrate 10 (such as an area marked with 50P in FIG. 1) may be larger than a projection area of the first patterned oxide semiconductor channel layer 22P in the thickness direction D3 (such as an area marked with 22P in FIG. 1), the projection area of the second patterned oxide semiconductor channel layer 40P in the thickness direction D3 may be larger than the projection area of the first patterned oxide semiconductor channel layer 22P in the thickness direction D3, and the projection area of the gate electrode 60G in the thickness direction D3 may also be larger than the projection area of the first patterned oxide semiconductor channel layer 22P in the thickness direction D3, but not limited thereto. Additionally, the projection area of the gate electrode 60G in the thickness direction D3 may be smaller than the projection area of the second patterned oxide semiconductor channel layer 40P in the thickness direction D3, and the side edge (such as a fifth side edge 60E shown in FIG. 2 and FIG. 3) may be not aligned with the fourth side edge 50E of the gate dielectric layer 50P and the third side edge 40E of the second patterned oxide semiconductor channel layer 40P.

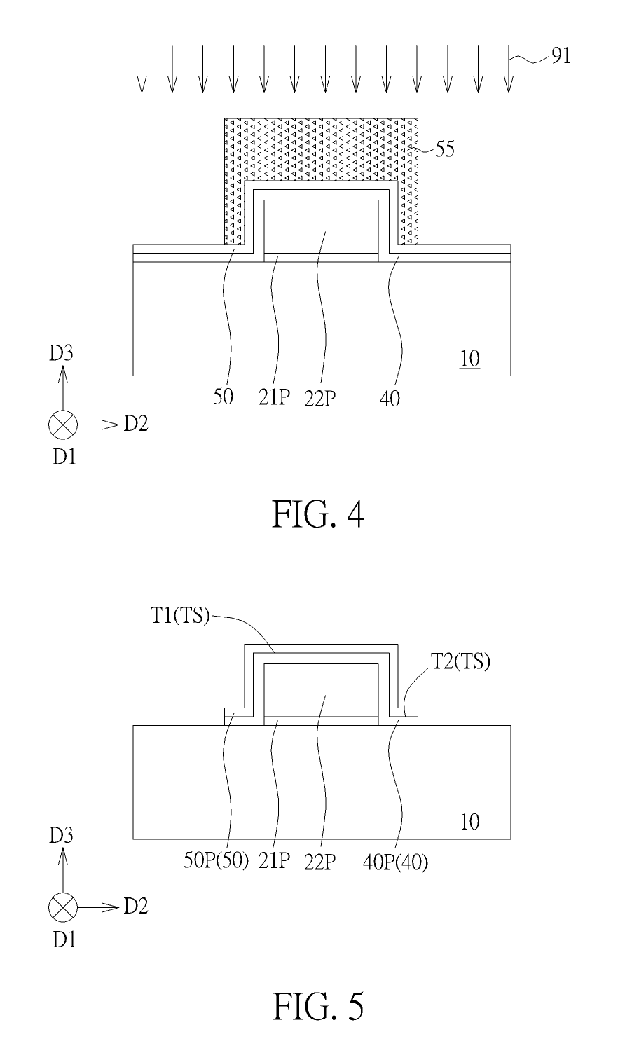

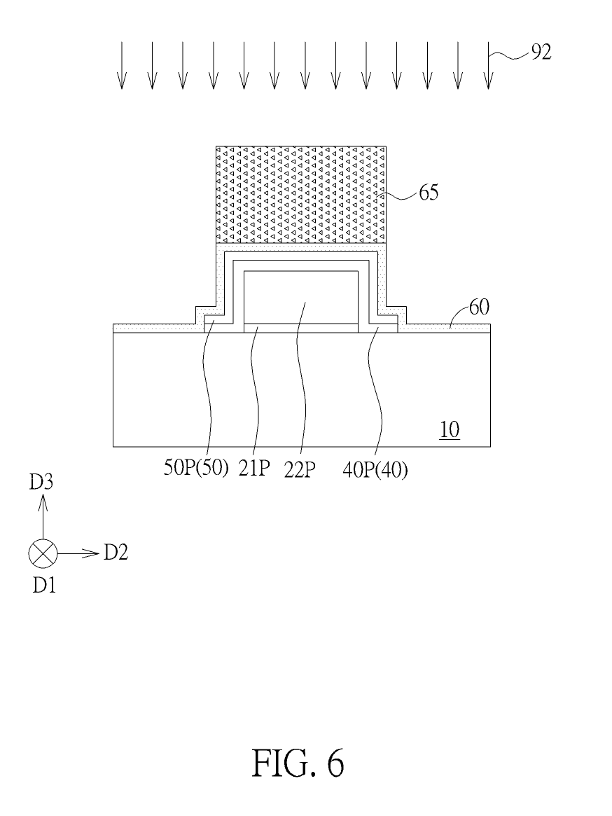

Please refer to FIGS. 4-6 and FIGS. 1-3. FIGS. 4-6 are schematic drawings illustrating a manufacturing method of the oxide semiconductor device according to the first embodiment of the present invention, and FIG. 2 may be regarded as a schematic drawing in a step subsequent to FIG. 6. As shown in FIGS. 1-3, the manufacturing method of the oxide semiconductor device in this embodiment may include the following steps. Firstly, the substrate 10 is provided. The first patterned oxide semiconductor channel layer 22P is formed on the substrate 10. The second patterned oxide semiconductor channel layer 40P is formed on the first patterned oxide semiconductor channel layer 22P. The second side edge 22E of the first patterned oxide semiconductor channel layer 22P is covered by the second patterned oxide semiconductor channel layer 40P. The gate dielectric layer 50P is formed on the second patterned oxide semiconductor channel layer 40P. The top surface TS of the second pattern oxide semiconductor channel layer 40P is fully covered by the gate dielectric layer 50P. The gate electrode 60G is formed on the gate dielectric layer 50P. The projection area of the gate electrode 60G in the thickness direction D3 of the substrate 10 is smaller than the projection area of the second patterned oxide semiconductor channel layer 40P in the thickness direction D3. Additionally, in some embodiments, the manufacturing method of the oxide semiconductor device may further include forming the source electrode 30S and the drain electrode 30D at two opposite sides of the first patterned oxide semiconductor channel layer 22P in the first direction D1 respectively and forming the third patterned oxide semiconductor channel layer 21P between the first patterned oxide semiconductor channel layer 22P and the substrate 10. Additionally, in some embodiments, the steps of forming the second patterned oxide semiconductor channel layer 40P and the gate dielectric layer 50P may include but are not limited to the following steps. As shown in FIG. 4, an oxide semiconductor layer 40 is formed on the first patterned oxide semiconductor channel layer 22P and the substrate 10, and a dielectric layer 50 is formed on the oxide semiconductor layer 40. A first patterning process 91 is then performed to the dielectric layer 50 and the oxide semiconductor layer 40. In the first patterning process 91, a first photoresist layer 55 may be formed on the dielectric layer 50, and an etching process may be performed with the first photoresist layer 55 as a mask, but not limited thereto. As shown in FIG. 4 and FIG. 5, the first photoresist layer 55 may be removed after the first patterning process 91. The dielectric layer 50 may be patterned to be the gate dielectric layer 50P by the first patterning process 91, and the oxide semiconductor layer 40 may be patterned to be the second patterned oxide semiconductor channel layer 40P by the first patterning process 91. In other words, the gate dielectric layer 50P and the second patterned oxide semiconductor channel layer 40P may be formed together by one identical patterning process.

Additionally, in some embodiments, the step of forming the gate electrode may include but is not limited to the following steps. As shown in FIGS. 4-6, a gate material layer 60 is formed on the substrate 10, the gate dielectric layer 50P, and the second patterned oxide semiconductor channel layer 40P after the first patterning process 91. A second patterning process 92 is then performed to the gate material layer 60. In the second patterning process 92, a second photoresist layer 65 may be formed on the gate material layer 60, and an etching process may be performed with the second photoresist layer 65 as a mask, but not limited thereto. As shown in FIG. 6 and FIG. 2, the second photoresist layer 65 may be removed after the second patterning process 92, and the gate material layer 60 may be patterned to be the gate electrode 60G by the second patterning process 92. In other words, the gate electrode 60G and the gate dielectric layer 50P may be formed and defined by different patterning processes, the first patterning process configured to form the gate dielectric layer 50P and the second patterned oxide semiconductor channel layer 40P may be performed before the step of forming the gate electrode 60G, and the second patterning process 92 configured to form the gate electrode 60G may be performed after the first patterning process, but not limited thereto. In some embodiments, the first patterning process may be performed after the step of forming the gate electrode 60G, and the gate dielectric layer 50P and the second patterned oxide semiconductor channel layer 40P may be defined by the first patterning process after the step of forming the gate electrode 60G. It is worth noting that the area of the second patterned oxide semiconductor channel layer 40P may be controlled because the second patterned oxide semiconductor channel layer 40 and the gate dielectric layer 50P may be formed and defined by the same patterning process, and the excessive overlapped area between the second patterned oxide semiconductor channel layer 40P and the gate electrode 60G outside the island shaped channel region composed of the first patterned oxide semiconductor channel layer 22P and the third patterned oxide semiconductor channel layer 21P may be avoided. The effective channel width of the oxide semiconductor device 101 may be effectively controlled, and the stability and the uniformity of electrical performance of the oxide semiconductor device 101 may be improved accordingly.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

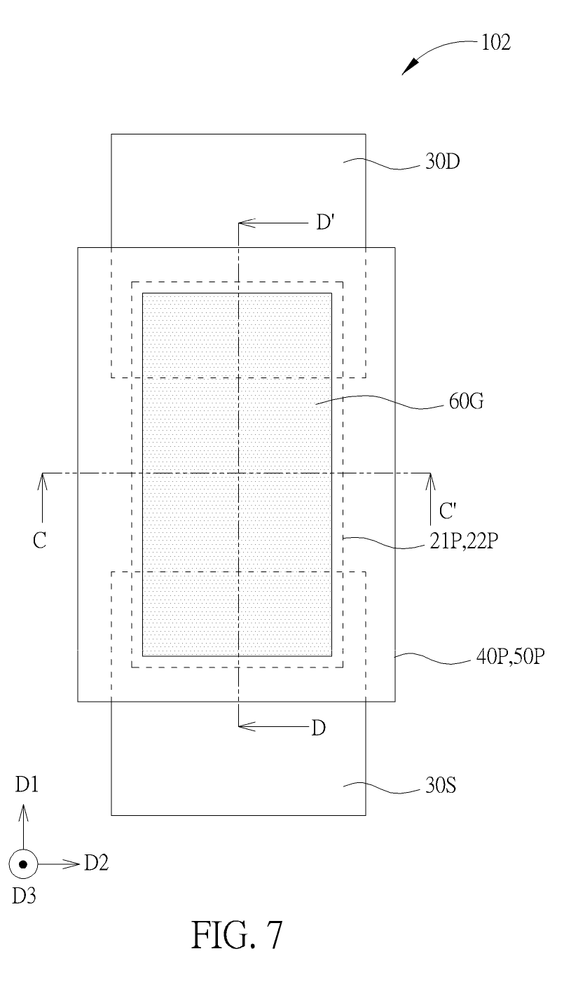

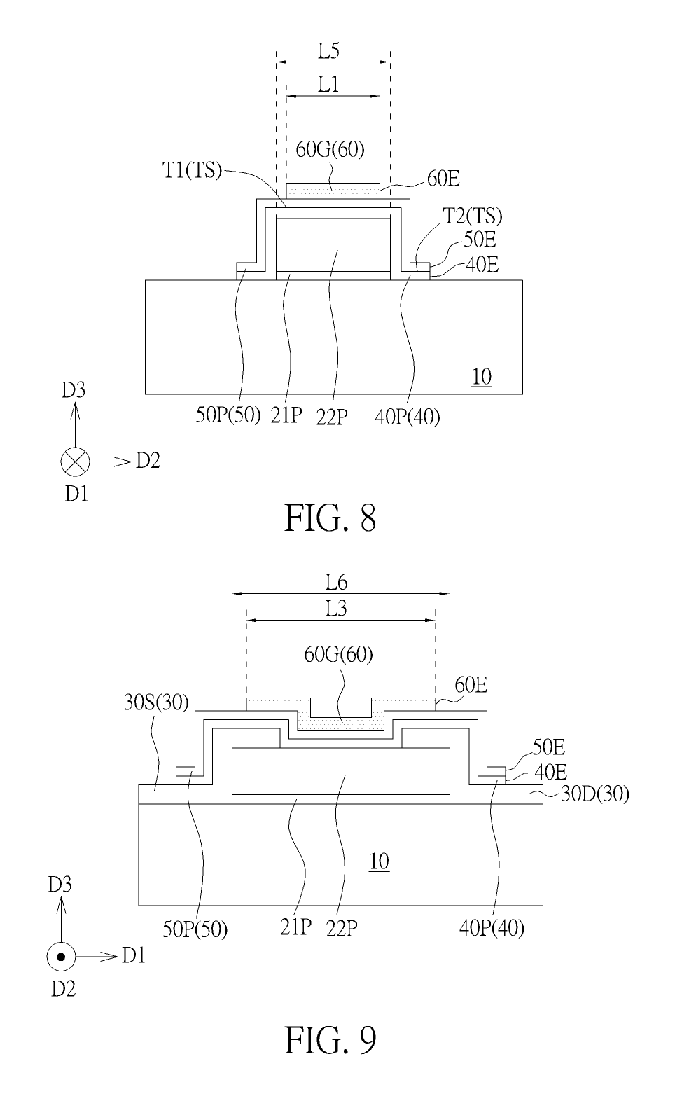

Please refer to FIGS. 7-9. FIG. 7 is a top view schematic drawing illustrating an oxide semiconductor device 102 according to a second embodiment of the present invention, FIG. 8 is a cross-sectional diagram taken along a line C-C′ in FIG. 7, and FIG. 9 is a cross-sectional diagram taken along a line D-D′ in FIG. 7. As shown in FIGS. 7-9, the difference between the oxide semiconductor device 102 in this embodiment and the oxide semiconductor device in the first embodiment mentioned above is that the gate electrode 60G in the oxide semiconductor device 102 of this embodiment may be relatively smaller for avoiding overlapping the second patterned oxide semiconductor channel layer 40P outside the island shaped channel region composed of the first patterned oxide semiconductor channel layer 22P and the third patterned oxide semiconductor channel layer 21P. In other words, the projection area of the gate electrode 60G in the thickness direction D3 of the substrate 10 (such as an area marked with 60G in FIG. 7) may be smaller than the projection area of the first patterned oxide semiconductor channel layer 22P in the thickness direction D3 (such as an area marked with 22P in FIG. 7). Additionally, in some embodiments, the first length L1 of the gate electrode 60G in the second direction D2 may be shorter than a length (such as a fifth length L5 shown in FIG. 8) of the first patterned oxide semiconductor channel layer 22P in the second direction D2, and the third length L3 of the gate electrode 60G in the first direction D1 may be shorter than a length (such as a sixth length L6 shown in FIG. 9) of the first patterned oxide semiconductor channel layer 22P in the first direction D1, but not limited thereto.

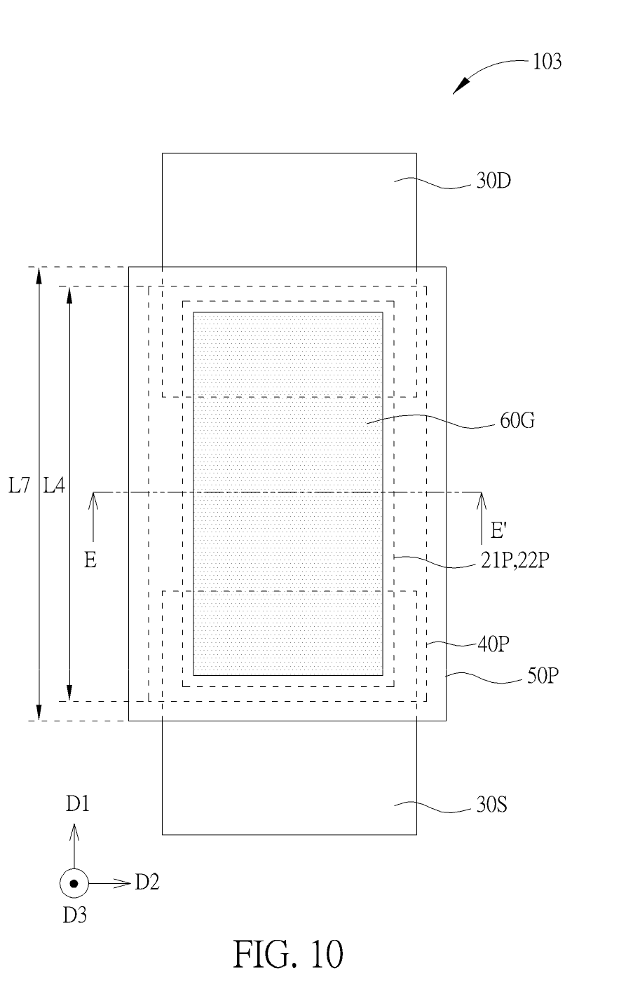

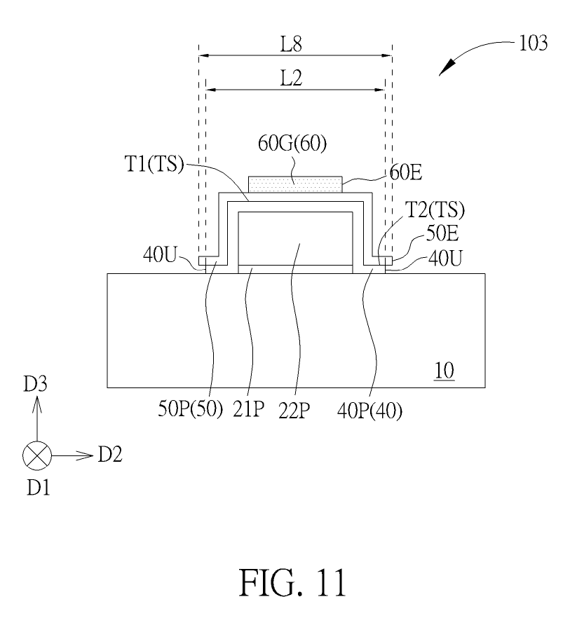

Please refer to FIG. 10 and FIG. 11. FIG. 10 is a top view schematic drawing illustrating an oxide semiconductor device 103 according to a third embodiment of the present invention, and FIG. 11 is a cross-sectional diagram taken along a line E-E′ in FIG. 10. As shown in FIG. 10 and FIG. 11, the difference between the oxide semiconductor device 103 in this embodiment and the oxide semiconductor device in the second embodiment mentioned above is that the second patterned oxide semiconductor channel layer 40P in the oxide semiconductor device 103 of this embodiment may include an undercut portion 40U disposed under the fourth side edge 50E of the gate dielectric layer 50P in the thickness direction D3 of the substrate 10. In some embodiments, the undercut portion 40U of the second patterned oxide semiconductor channel layer 40P may be formed by modifying the etching selectivity of the etching process configured to define the second patterned oxide semiconductor channel layer 40P and the gate dielectric layer 50P, such as the above-mentioned etching process of the first patterning process 91 shown in FIG. 4, but not limited thereto. In addition, the projection area of the second patterned oxide semiconductor channel layer 40P in the thickness direction D3 (such as an area marked with 40P in FIG. 10) may be smaller than the projection area of the gate dielectric layer 50P in the thickness direction D3 (such as an area marked with 50P in FIG. 10), the fourth length L4 of the second patterned oxide semiconductor channel layer 40P in the first direction D1 may be shorter than a length (such as a seventh length L7 shown in FIG. 10) of the gate dielectric layer 50P in the first direction D1, and the second length L2 of the second patterned oxide semiconductor channel layer 40P in the second direction D2 may be shorter than a length (such as an eighth length L8 shown in FIG. 11) of the gate dielectric layer 50P in the second direction D2, but not limited thereto. The second patterned oxide semiconductor channel layer 40P will not extend outside the gate dielectric layer 50P by the formation of the undercut portion 40U, and the stability of the electrical performance of the oxide semiconductor device 103 may be further improved.

To summarize the above descriptions, in the oxide semiconductor device and the manufacturing thereof according to the present invention, the second patterned oxide semiconductor channel layer and the gate dielectric layer may be formed by the same patterning process, the top surface of the second patterned oxide semiconductor channel layer may be fully covered by the gate dielectric layer, and the area of the second patterned oxide semiconductor channel layer may be controlled accordingly. By the method of forming the second patterned oxide semiconductor channel layer in the present invention, the excessive overlapped area between the second patterned oxide semiconductor channel layer and the gate electrode outside the area of the first patterned oxide semiconductor channel layer may be avoided. The effective channel width of the oxide semiconductor device may be effectively controlled, and the stability and the uniformity of electrical performance of the oxide semiconductor device may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

1. An oxide semiconductor device, comprising:
a substrate;
a first patterned oxide semiconductor channel layer disposed on the substrate;
a second patterned oxide semiconductor channel layer disposed on the first patterned semiconductor channel layer, wherein a side edge of the first patterned oxide semiconductor channel layer is covered by the second patterned oxide semiconductor channel layer;
a gate dielectric layer disposed on the second patterned oxide semiconductor channel layer, wherein a top surface of the second pattern oxide semiconductor channel layer is fully covered by the gate dielectric layer; and
a gate electrode disposed on the gate dielectric layer, wherein a projection area of the gate electrode in a thickness direction of the substrate is smaller than a projection area of the second patterned oxide semiconductor channel layer in the thickness direction, and a part of a top surface of the gate dielectric layer is not covered by the gate electrode, wherein the projection area of the second patterned oxide semiconductor channel layer in the thickness direction is larger than a projection area of the first patterned oxide semiconductor channel layer in the thickness direction in plan view.

2. The oxide semiconductor device according to claim 1, wherein a side edge of the second patterned oxide semiconductor channel layer is aligned with a side edge of the gate dielectric layer in plan view.

3. The oxide semiconductor device according to claim 1, wherein the second patterned oxide semiconductor channel layer comprises an undercut portion disposed under a side edge of the gate dielectric layer.

4. The oxide semiconductor device according to claim 1, wherein the projection area of the second patterned oxide semiconductor channel layer in the thickness direction is smaller than a projection area of the gate dielectric layer in the thickness direction.

5. The oxide semiconductor device according to claim 1, further comprising:
a source electrode and a drain electrode, wherein the source electrode and the drain electrode are disposed at two opposite sides of the first patterned oxide semiconductor channel layer in a first direction respectively, wherein the second patterned oxide semiconductor channel layer is conformal to the first patterned oxide semiconductor channel layer and conformal to the source electrode and the drain electrode, respectively.

6. The oxide semiconductor device according to claim 5, wherein a length of the gate electrode in the first direction is shorter than a length of the second patterned oxide semiconductor channel layer in the first direction.

7. The oxide semiconductor device according to claim 5, wherein a length of the gate electrode in a second direction orthogonal to the first direction is shorter than a length of the second patterned oxide semiconductor channel layer in the second direction.

8. The oxide semiconductor device according to claim 5, wherein a part of the source electrode and a part of the drain electrode are covered by the second patterned oxide semiconductor channel layer.

9. The oxide semiconductor device according to claim 1, wherein a side edge of the gate electrode is not aligned with a side edge of the gate dielectric layer and a side edge of the second patterned oxide semiconductor channel layer.

10. The oxide semiconductor device according to claim 1, further comprising:
a third patterned oxide semiconductor channel layer disposed between the first patterned oxide semiconductor channel layer and the substrate, wherein a side edge of the third patterned oxide semiconductor channel layer is covered by the second patterned oxide semiconductor channel layer.

11. A manufacturing method of an oxide semiconductor device, comprising:
providing a substrate;
forming a first patterned oxide semiconductor channel layer on the substrate;
forming a second patterned oxide semiconductor channel layer on the first patterned oxide semiconductor channel layer, wherein a side edge of the first patterned oxide semiconductor channel layer is covered by the second patterned oxide semiconductor channel layer;
forming a gate dielectric layer on the second patterned oxide semiconductor channel layer, wherein a top surface of the second pattern oxide semiconductor channel layer is fully covered by the gate dielectric layer; and
forming a gate electrode on the gate dielectric layer, wherein a projection area of the gate electrode in a thickness direction of the substrate is smaller than a projection area of the second patterned oxide semiconductor channel layer in the thickness direction, and a part of a top surface of the gate dielectric layer is not covered by the gate electrode, wherein the projection area of the second patterned oxide semiconductor channel layer in the thickness direction is larger than a projection area of the first patterned oxide semiconductor channel layer in the thickness direction in plan view.

12. The manufacturing method of the oxide semiconductor device according to claim 11, wherein the steps of forming the second patterned oxide semiconductor channel layer and the gate dielectric layer comprise:
forming an oxide semiconductor layer on the first patterned oxide semiconductor channel layer and the substrate;
forming a dielectric layer on the oxide semiconductor layer; and
performing a first patterning process to the dielectric layer and the oxide semiconductor layer, wherein the dielectric layer is patterned to be the gate dielectric layer by the first patterning process, and the oxide semiconductor layer is patterned to be the second patterned oxide semiconductor channel layer by the first patterning process.

13. The manufacturing method of the oxide semiconductor device according to claim 12, wherein the first patterning process is performed before the step of forming the gate electrode.

14. The manufacturing method of the oxide semiconductor device according to claim 12, wherein the step of forming the gate electrode comprises:
forming a gate material layer on the substrate, the gate dielectric layer, and the second patterned oxide semiconductor channel layer after the first patterning process; and
performing a second patterning process to the gate material layer, wherein the gate material layer is patterned to be the gate electrode by the second patterning process.

15. The manufacturing method of the oxide semiconductor device according to claim 11, further comprising:
forming a source electrode and a drain electrode at two opposite sides of the first patterned oxide semiconductor channel layer in a first direction respectively wherein the second patterned oxide semiconductor channel layer is conformal to the first patterned oxide semiconductor channel layer and conformal to the source electrode and the drain electrode, respectively.

16. The manufacturing method of the oxide semiconductor device according to claim 15, wherein a length of the gate electrode in the first direction is shorter than a length of the second patterned oxide semiconductor channel layer in the first direction.

17. The manufacturing method of the oxide semiconductor device according to claim 15, wherein a length of the gate electrode in a second direction orthogonal to the first direction is shorter than a length of the second patterned oxide semiconductor channel layer in the second direction.

18. The manufacturing method of the oxide semiconductor device according to claim 11, wherein a side edge of the second patterned oxide semiconductor channel layer is aligned with a side edge of the gate dielectric layer in plan view.

19. The manufacturing method of the oxide semiconductor device according to claim 11, wherein the second patterned oxide semiconductor channel layer comprises an undercut portion disposed under a side edge of the gate dielectric layer.

20. The manufacturing method of the oxide semiconductor device according to claim 11, wherein the projection area of the second patterned oxide semiconductor channel layer in the thickness direction is smaller than a projection area of the gate dielectric layer in the thickness direction.
